(19) United States
(12) Patent Application Publication
(10) Pub. No.: US 2016/0251752 A1
(43) Pub. Date: Sep. 1, 2016

(54) LINEAR EVAPORATION SOURCE

(71) Applicants: BOE TECHNOLOGY GROUP CO., LTD., Beijing (CN); ORDOS YUANSHENG OPTOELECTRONICS CO., LTD., Ordos, Inner Mongolia (CN)

(72) Inventor: Ang XIAO, Beijing (CN)

(73) Assignees: ORDOS YUANSHENG OPTOELECTRONICS CO., LTD., Dongsheng District, Ordos (CN); BOE TECHNOLOGY GROUP CO., LTD., Beijing (CN)

(21) Appl. No.: 14/770,155

(22) PCT Filed: Nov. 6, 2014
(86) PCT No.: PCT/CN2014/090482

§ 371 Date: Aug. 25, 2015

(30) Foreign Application Priority Data
Aug. 14, 2014 (CN) 201410400453.3

(51) Int. Cl. C23C 14/24

(52) U.S. Cl. CPC C23C 14/243

(57) ABSTRACT

The invention has disclosed an linear evaporation source comprising a shell and a crucible provided in the shell, wherein the crucible comprises a crucible body and a nozzle, a heating device for heating the crucible body is provided outside the crucible body, and a heat-insulation device for preventing heat from dissipating to the shell is provided between the shell and the heating device. In the linear evaporation source of the invention, a heat-insulation device for preventing heat from dissipating to the shell is provided between the shell and the heating device, thus the energy dissipation of the heating device during heating may be reduced effectively, and since the thermal radiation of the heating device to the inner wall of the shell is reduced, the service life may be prolonged.

### CROSS REFERENCE TO RELATED APPLICATION

The present application claims priority to the Chinese application No. 201410400453.3 filed in China on Aug. 14, 2014, the entire content of which is incorporated by reference.

### FIELD OF THE INVENTION

The present invention relates to the field of evaporation, and in particular, to an linear evaporation source.

### DESCRIPTION OF THE PRIOR ART

In the production of an existing OLED panel, an evaporation process is usually employed for attaching a luminescent material to a substrate, and in a batch production, a linear evaporation source (linear source, for short) is required for evaporating the luminescent material. For an existing linear evaporation source, the luminescent material is filled in the linear evaporation source and then sealed tightly before evaporation. During evaporation, a vacuum state is maintained inside and outside the linear source, and the linear evaporation source is heated by a heating device for evaporating the material inside, and at the same time, a cooling device cools the outer wall of the linear evaporation source so as to prevent an apparatus outside the linear source from being damaged by excess heat.

However, the design of the existing linear source has the following problems:

1) A part of heat energy of the heating device is lost during the heat exchange with the cooling device;

2) Because the inside and outside of the inner wall of the linear source are directly acted by the thermal radiation and the cooling device respectively that have a large thermal difference, the inner wall of the linear source tends to be damaged by long-term evaporation.

### SUMMARY OF THE INVENTION

In order to solve the problem of the existing linear evaporation source that the inner wall of linear source tends to be damaged, the invention provides an linear evaporation source.

The technical solution employed by the invention is as follows:

An linear evaporation source, which includes a shell and a crucible provided in the shell, wherein the crucible includes a crucible body and a nozzle, a heating device for heating the crucible body is provided outside the crucible body, and a heat-insulation device for preventing heat from dissipating to the shell is provided between the shell and the heating device.

Wherein, the heat-insulation device is provided with a reflecting layer in the direction facing the crucible body.

Wherein, a mesopore for preventing deformation is provided on the reflecting layer.

Wherein, the heat-insulation device surrounds the crucible body, and the heat-insulation device is provided with an opening at a position corresponding to the nozzle.

Wherein, the heat-insulation device further includes a base for bearing the reflecting layer.

Wherein, the reflecting layer includes a heat-reflecting material layer and a membranous layer for attaching the heat-reflecting material layer to the base.

Wherein, the heat-reflecting material includes lanthanide metal oxide-doped NaZn(PO₄), aluminium-doped NaZn(PO₄) or alumina-doped NaZn(PO₄).

Wherein, the lanthanide metal oxide has an amount of 0.1%-1% by weight of the NaZn(PO₄), and the aluminium or the alumina has an amount of 0.5-2% by weight of the NaZn(PO₄).

Wherein, the distance from the reflecting layer to the crucible is greater than 2 cm.

Wherein, the linear evaporation source further includes: a cooling device for cooling the shell, which is provided on one side of the shell that is close to the crucible body, or on one side of the shell that is far from the crucible body, or in the chamber of the shell.

The invention has the advantageous effects as follows: for the linear evaporation source of the invention, a heat-insulation device for preventing heat from dissipating to the shell is provided between the shell and the crucible body of the crucible, thus the energy dissipation of the heating device during heating may be reduced effectively, and since the thermal radiation of the heating device to the inner wall of the shell is reduced, the service life may be prolonged.

### BRIEF DESCRIPTION OF THE DRAWINGS

FIG. 1 shows a structural representation of an linear evaporation source according to one embodiment of the invention;

FIG. 2 shows a sectional view of FIG. 1;

FIG. 3 is a diagram showing the distribution of mesopores of a heat-insulation device on the linear evaporation source according to one embodiment of the invention; and

FIG. 4 shows a sectional view of the heat-insulation device on the linear evaporation source according to one embodiment of the invention.

### DETAILED DESCRIPTION OF THE PREFERRED EMBODIMENTS

In order to make the technical problem to be solved, the technical solutions and the advantages of the invention more apparent, a detail description will be given below in conjunction with the drawings and specific embodiments.

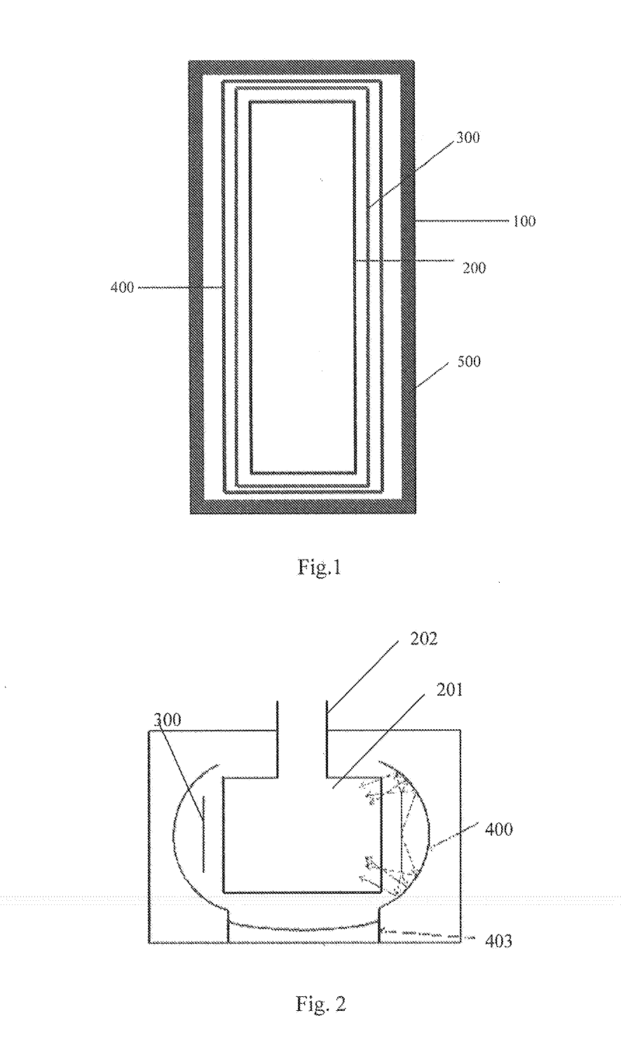

As shown in FIG. 1, it shows a structural representation of an linear evaporation source according to one embodiment of the invention. The linear evaporation source of this embodiment includes a shell 100 and a crucible 200 provided in the shell 100, a heating device 300 for heating the crucible 200 is provided outside the crucible 200, and a heat-insulation device 400 for preventing heat from dissipating to the shell 100 is provided between the shell 100 and the heating device 300.

For the linear evaporation source of the invention, a heat-insulation device for preventing heat from dissipating to the shell is provided between the shell and the heating device of the crucible, thus the energy dissipation of the heating device during heating may be reduced effectively, and since the thermal radiation of the heating device to the inner wall of the shell is reduced, the service life may be prolonged.

Again referring to FIG. 1, the linear evaporation source of the invention further includes a cooling device 500 for cooling the shell, The cooling device 500 may have various structures that are suitable for cooling the shell. In this embodiment, a liquid cooling bag is employed, which may be provided on one side of the shell that is close to the crucible, or on one side of the shell that is far from the crucible, or in the chamber of the shell. Preferably, a circulating liquid is provided in the liquid cooling bag so that the shell may be cooled continuously. The circulating liquid may be a liquid such as water or cooling oil, and thus the shell may be cooled circularly, and the temperature of the shell may be lowered.

As shown in FIG. 2, the crucible 200 includes a crucible body 201 and a nozzle 202. A heat-insulation device 300 is fixed to the bottom of the linear source via a base 403. In this embodiment, the heat-insulation device surrounds the crucible body 201, and the heat-insulation device 300 is provided with an opening at a position corresponding to the nozzle 202 of the crucible so as to match the crucible body of the crucible. In this embodiment, the crucible body of the crucible may be quadrangular or circular, etc.

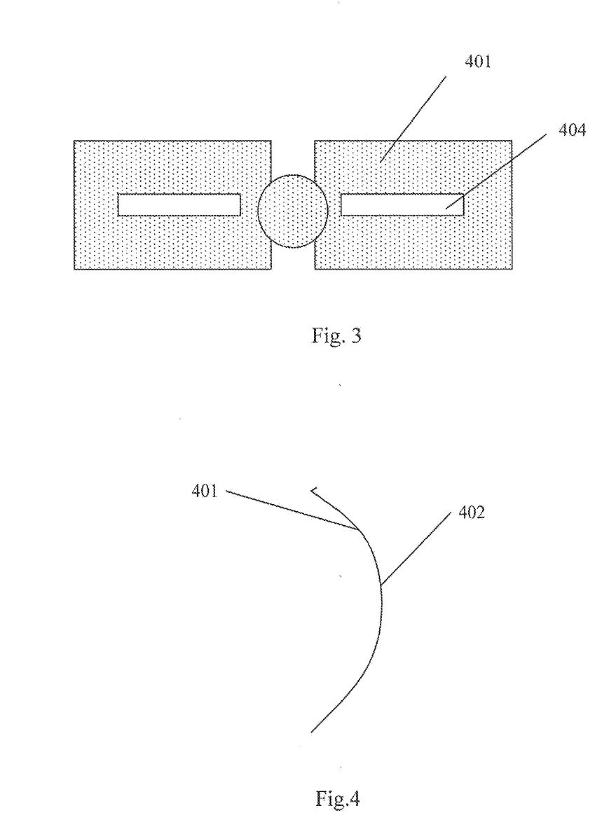

The heat-insulation device of the invention is adapted to prevent the heating device from dissipating heat to the shell. As shown in FIG. 3, the heat-insulation device 300 is provided with a reflecting layer 401 in the direction facing the crucible body so that heat may be reflected back to the crucible body, and thus heat loss may be avoided. A mesopore 404 for preventing deformation is provided on the reflecting layer. Since the reflecting layer will expand under the action of the heating device, the reflecting layer may be broken and it's service life will be negatively influenced. Therefore, in embodiment of the invention, a plurality of mesopores are provided in the reflecting layer, and the mesopores are distributed uniformly so that the break of the reflecting layer caused by expansion may be avoided. Preferably, the base of the heat-insulation device is also provided with a gap at a position corresponding to the mesopore on the reflecting layer so that a through hole may be formed on the heat-insulation device. The size and shape of the through hole may be provided as required. The mesopore may have a shape of a strip, which is distributed symmetrically on the heat-insulation device. In the embodiment of the invention, a mesopore is formed on the heat-insulation device, thus break of the heat-insulation device caused by heating may be reduced greatly. However, if the heat-insulation device employs a material with enough strength, no mesopore may be provided. At this time, the cost required will be added.

As shown in FIG. 4, in this embodiment, the heat-insulation device has a plate-shape structure, and it includes a plate-shape base 402 and a reflecting layer 401 that is formed on the plate-shape base of the heat-insulation device in the direction facing the crucible. The plate-shape base 402 is provided in a direction on the heat-insulation device that is far from the crucible, and the material of the plate-shape base 402 may be aluminium or a copper alloy. In this embodiment, the plate-shape heat-insulation device is consisted of a plurality of arcwall faces, and it forms a structure that matches the crucible body. In this embodiment, the reflecting layer 401 of the heat-insulation device includes a heat-reflecting material layer and a membranous layer for attaching the heat-reflecting material layer to the plate-shape base 402. The heat-reflecting material layer is made of a heat-reflecting material so that the heat received from the crucible will be reflected. Preferably, the heat-reflecting material includes lanthanide metal oxide-doped NaZn(PO₄), aluminium-doped NaZn(PO₄) or alumina-doped NaZn(PO₄). The distance from the reflecting layer to the crucible is greater than 2 cm so that the heat radiated to the heat-insulation device from the crucible may be reduced. However, in the invention, the distance from the reflecting layer to the crucible may be designed according to the size of the specific linear source, and the distance may also be adjusted as required. In this embodiment, a methyl or ethyl or propyl or isopropyl or butyl or tertiary butyl or isobutyl acrylic acid latex is employed as the membranous layer so that the heat-reflecting material may be attached to the base. Preferably, the lanthanide metal is lanthanum, europium, cerium or neodymium. The lanthanide metal oxide has an amount of 0.1%-1% by mole of the NaZn(PO₄), and aluminium or alumina has an amount of 0.5-2% by mole of the NaZn(PO₄).

In the embodiment of the present invention, a heat-insulation device for preventing heat from dissipating to the shell is provided between the shell and the crucible body of the crucible, thus the energy dissipation of the heating device during heating may be reduced effectively, and since the thermal radiation of the heating device to the inner wall of the shell is reduced, the service life may be prolonged.

The above description only shows some exemplary embodiments of the invention. It should be pointed that, for one of ordinary skills in the art, various improvements and modifications may also be made without departing from the technical principles of the invention, and these improvements and modifications should also be regarded as the protection scope of the invention.

1. An linear evaporation source, comprising a shell (100) and a crucible (200) provided in the shell (100), wherein the crucible (200) comprises a crucible body (201) and a nozzle (202), a heating device (300) for heating the crucible body is provided outside the crucible body (201), and a heat-insulation device (400) for preventing heat from dissipating to the shell (100) is provided between the shell (100) and the heating device (300).

2. The linear evaporation source according to claim 1, wherein the heat-insulation device (400) is provided with a reflecting layer (401) in the direction facing the crucible body (201).

3. The linear evaporation source according to claim 2, wherein a mesopore (404) for preventing deformation is provided on the reflecting layer (401).

4. The linear evaporation source according to claim 3, wherein the heat-insulation device (400) surrounds the crucible body (201), and the heat-insulation device (400) is provided with an opening at a position corresponding to the nozzle (202).

5. The linear evaporation source according to claim 3, wherein the heat-insulation device (400) further comprises a base (402) for bearing the reflecting layer (401).

6. The linear evaporation source according to claim 5, wherein the reflecting layer (401) comprises a heat-reflecting material layer and a membranous layer for attaching the heat-reflecting material layer to the base.

7. The linear evaporation source according to claim 6, wherein the heat-reflecting material includes lanthanide metal oxide-doped NaZn(PO₄), aluminium-doped NaZn(PO₄) or alumina-doped NaZn(PO₄).

8. The linear evaporation source according to claim 7, wherein the lanthanide metal oxide has an amount of 0.1%-1% by weight of the NaZn(PO₄), and the aluminium or the alumina has an amount of 0.5-2% by weight of the NaZn(PO₄).

9. The linear evaporation source according to claim 2, wherein the distance from the reflecting layer (401) to the crucible (200) is greater than 2 cm.

10. The linear evaporation source according to 1, wherein the linear evaporation source further comprises a cooling device (500) for cooling the shell, which is provided on one side of the shell (100) that is close to the crucible body (201), or on one side of the shell (100) that is far from the crucible body (201), or in the chamber of the shell (100).

11. The linear evaporation source according to claim 3, wherein the distance from the reflecting layer (401) to the crucible (200) is greater than 2 cm.

12. The linear evaporation source according to claim 4, wherein the distance from the reflecting layer (401) to the crucible (200) is greater than 2 cm.

13. The linear evaporation source according to claim 5, wherein the distance from the reflecting layer (401) to the crucible (200) is greater than 2 cm.

14. The linear evaporation source according to claim 6, wherein the distance from the reflecting layer (401) to the crucible (200) is greater than 2 cm.

15. The linear evaporation source according to claim 7, wherein the distance from the reflecting layer (401) to the crucible (200) is greater than 2 cm.

16. The linear evaporation source according to claim 8, wherein the distance from the reflecting layer (401) to the crucible (200) is greater than 2 cm.

17. The linear evaporation source according to claim 2, wherein the linear evaporation source further comprises a cooling device (500) for cooling the shell, which is provided on one side of the shell (100) that is close to the crucible body (201), or on one side of the shell (100) that is far from the crucible body (201), or in the chamber of the shell (100).

18. The linear evaporation source according to claim 4, wherein the linear evaporation source further comprises a cooling device (500) for cooling the shell, which is provided on one side of the shell (100) that is close to the crucible body (201), or on one side of the shell (100) that is far from the crucible body (201), or in the chamber of the shell (100).

19. The linear evaporation source according to claim 5, wherein the linear evaporation source further comprises a cooling device (500) for cooling the shell, which is provided on one side of the shell (100) that is close to the crucible body (201), or on one side of the shell (100) that is far from the crucible body (201), or in the chamber of the shell (100).

20. The linear evaporation source according to claim 6, wherein the linear evaporation source further comprises a cooling device (500) for cooling the shell, which is provided on one side of the shell (100) that is close to the crucible body (201), or on one side of the shell (100) that is far from the crucible body (201), or in the chamber of the shell (100).
